(19) United States
(12) Patent Application Publication
(10) Pub. No.: US 2009/0153161 A1
(43) Pub. Date: Jun. 18, 2009

(54) Probe Holder and Probe Unit

(76) Inventors: Koji Ishikawa, Kanagawa (JP); Jun Tominaga, Kanagawa (JP); Taiichi Rikimaru, Kanagawa (JP)

Correspondence Address: EDWARDS ANGELL PALMER & DODGE LLP, P.O. BOX 55874, BOSTON, MA, 02205, US

(21) Appl. No.: 12/085,043

(22) PCT Filed: Nov. 21, 2006
(86) PCT No.: PCT/JP2006/323196

§ 371 Date: Feb. 5, 2009

(30) Foreign Application Priority Data
Nov. 22, 2005 (JP) 2005-337213

(51) Int. Cl. G01R 1/067

(52) U.S. Cl. 324/754

(57) ABSTRACT

A probe holder is for containing a plurality of probes for inputting and outputting an electrical signal to and from a circuitry when the probes come in contact with the circuitry. The probe holder includes a distal end for holding the probes; a proximal end that supports the distal end; and a flexure-causing unit between the distal end and the proximal end to cause a flexure of the distal end relative to the proximal end.

### TECHNICAL FIELD

The present invention relates to a probe holder and a probe unit that hold a plurality of probes that come in contact with a circuitry of, for example, a liquid crystal display and an integrated circuit, so as to input and output electrical signals, when testing the conductive state or operating characteristics of such a circuitry.

### BACKGROUND ART

Probes have been used in general to test the conductive state or operating characteristics of. circuitries of, for example, liquid crystal displays (LCDs) and integrated circuits. A large number of connecting electrodes or terminals formed on a test object such as an LCD are arranged at small and narrow intervals, and probes are arranged in a probe unit so as to correspond to a large number of connecting electrodes or terminals formed on the test object. Such a probe unit having the above structure for making an electrical connection with the test object has been employed (for example, see Patent Document 1). This technology has a feature that a plurality of probes each having a beam shape are formed on a substrate surface at one time by lithography technology, thereby arranging the connecting electrodes or terminals at narrow intervals in the circuitry.

Patent Document 1: Japanese Patent Application Laid-Open No. 2002-151557

### DISCLOSURE OF INVENTION

### Problem to be Solved by the Invention

The related art, however, has a problem in that when a test object having a large warp of a substrate such as an LCD is tested, making a contact with the substrate gives an extremely small stroke. To solve this problem to ensure a stroke large enough as required for testing, a large load needs to be applied to the probes. Applying such a large load may cause a problem with durability of the probes.

In addition, to increase accuracy of contact positions of the probes formed by photolithography with high accuracy, production cost is increased. Further, exchanging the probes for maintenance also leads to cost increase. Thus, the related art has not necessarily had economic advantages.

The present invention is made in view of the foregoing, and has an object to provide a probe holder and a probe unit that ensure a desirable stroke when coming in contact with a test object, i.e. a circuitry, so as to achieve excellent durability and economic advantages.

### Means for Solving Problem

To solve the above problems and achieve the object, a probe holder according to the present invention is for containing a plurality of probes for inputting and outputting an electrical signal to and from a circuitry when the probes come in contact with the circuitry, the probe holder including a distal end for holding the probes; a proximal end that supports the distal end; and a flexure-causing unit between the distal end and the proximal end to cause a flexure of the distal end relative to the proximal end.

According to the probe holder of the present invention, in the above invention, the flexure-causing unit has at least a portion formed integrally with the distal end and the proximal end and having a beam shape with a thickness smaller than thicknesses of the distal end and the proximal end.

According to the probe holder of the present invention, in the above invention, the flexure-causing unit includes an elastic member that connects the distal end and the proximal end.

According to the probe holder of the present invention, in the above invention, the elastic member includes at least one spring plate.

A probe unit according to the present invention includes a plurality of probes for inputting and outputting an electrical signal to and from a circuitry when the probes come in contact with the circuitry; and a probe holder including a distal end for holding the probes, a proximal end that supports the distal end, and a flexure-causing unit between the distal end and the proximal end to cause a flexure of the distal end relative to the proximal end.

According to the probe unit of the present invention, in the above invention, the flexure-causing unit has at least a portion formed integrally with the distal end and the proximal end and having a beam shape with a thickness smaller than thicknesses of the distal end and the proximal end.

According to the probe unit of the present invention, in the above invention, the flexure-causing unit includes an elastic member that connects the distal end and the proximal end.

According to the probe unit of the present invention, in the above invention, the elastic member includes at least one spring plate.

According to the probe unit of the present invention, in the above invention, the probes include wiring formed on a surface of a sheet-like base, and a contact section arranged on one-end of the wiring and coming into direct contact with the circuitry.

### EFFECT OF THE INVENTION

According to the present invention, a probe holder and a probe unit are provided that include a distal end for holding a plurality of probes for inputting and outputting an electrical signal to and from a circuitry when the probes come in contact with the circuitry; a proximal end that supports the distal end; and a flexure-causing unit that resides between the distal end and the proximal end and causes a flexure of the distal end relative to the proximal end. With this structure, the probe holder and the probe unit ensure a desirable stroke when coming in contact with a test object, i.e. a circuitry, thereby achieving excellent durability and economic advantages.

### BRIEF DESCRIPTION OF DRAWINGS

FIG. 1 is schematic of a probe unit that includes a probe holder according to a first embodiment of the present invention.

FIG. 2 is an external view of relevant portions of the probe unit.

FIG. 3 is a bottom view of a portion near a distal end of the probe unit.

FIG. 4 is a schematic for explaining a stroke that occurs when a load is applied to the probe holder according to the first embodiment of the present invention.

FIG. 5 is a schematic of a probe holder according to a modification of the first embodiment of the present invention.

FIG. 6 is a schematic of a probe unit that includes a probe holder according to a second embodiment of the present invention.

FIG. 7 is a top view of a flexure-causing section of the probe holder according to the second embodiment of the present invention.

FIG. 8 is a schematic for explaining a stroke that occurs when a load is applied to the probe holder according to the second embodiment of the present invention.

FIG. 9 is a top view of another structure of the flexure-causing section of the probe holder according to the second embodiment of the present invention.

FIG. 10 is a schematic of a probe holder according to a first modification of the second embodiment of the present invention.

FIG. 11 is a schematic of a probe holder according to a second modification of the second embodiment of the present invention.

FIG. 12 is a schematic of a probe holder according to a third embodiment of the present invention.

FIG. 13 is a schematic of a probe holder according to a modification of the third embodiment of the present invention.

FIG. 14 is a schematic of a probe holder according to a fourth embodiment of the present invention.

FIG. 15 is a schematic of a probe holder according to a fifth embodiment of the present invention.

### EXPLANATIONS OF LETTERS OR NUMERALS

1, 10 Probe-unit

2 Probe sheet

3, 6, 7, 9, 11, 12, 12-2, 13, 14 Probe holder

3a, 6a, 7a, 9a, 11a, 12a, 13a, 14a Front end

3b, 6b, 7b, 9b, 11b, 12b, 13b, 14b Base end

3c, 6c, 7c, 9c, 11c, 12c, 12-2c, 13c, 14c Flexure-causing section (flexure-causing unit)

4 Fixing member

5 Adjustment mechanism

21 Base

22 Bump (contact section)

23 Wire

31, 61, 71, 91, 111, 121, 131, 141 Protruding portion

32, 62, 72, 92, 112, 122, 132, 133, 142 Opening

33 Groove

34, 63, 134, 135, 143 Small-thickness portion

51 First block member

52 Second block member

81, 84 Plate spring

82 Fixing plate

83 Screw

100 Signal processor

200 Test object

### BEST MODE(S) FOR CARRYING OUT THE INVENTION

Referring to the accompanying drawings, the following describes exemplary embodiments (hereinafter, “embodiments”) for carrying out the present invention. Note that the drawings are schematics and the relationship between the thickness and the width of elements, the ratio of the thicknesses of the elements, for example, may be different from those actually measured. Needless to say, some elements may be different between figures regarding the dimensional relationship or ratio.

### First Embodiment

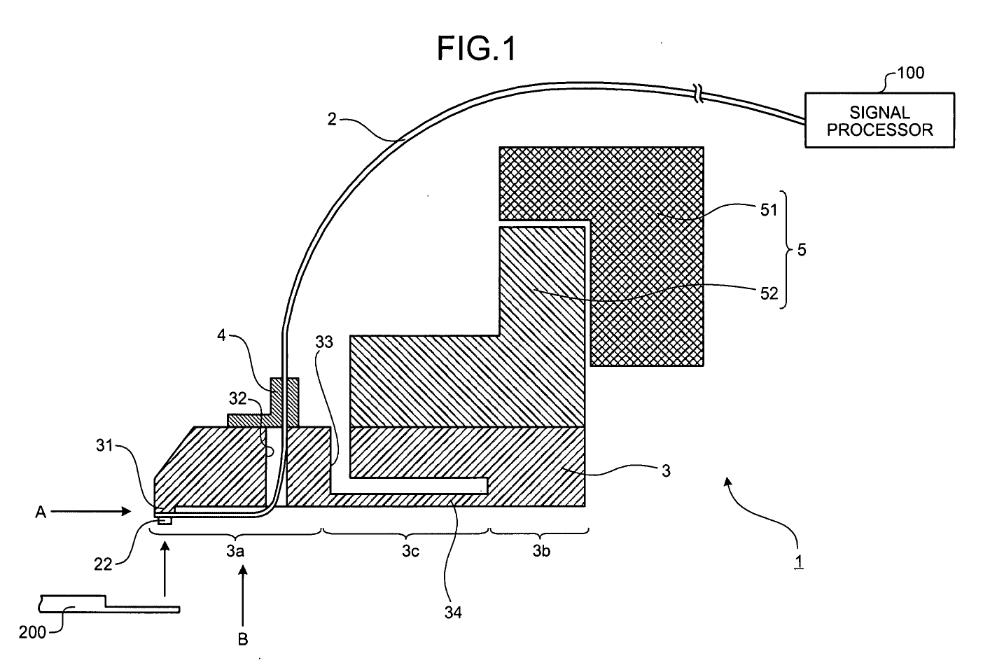

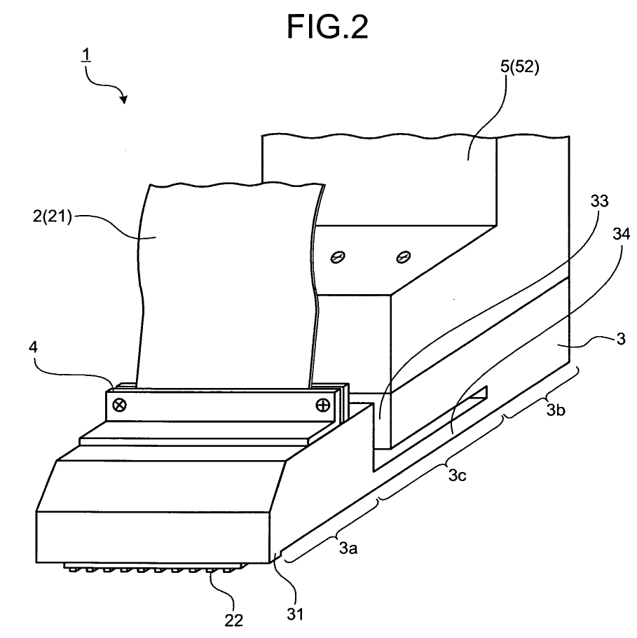

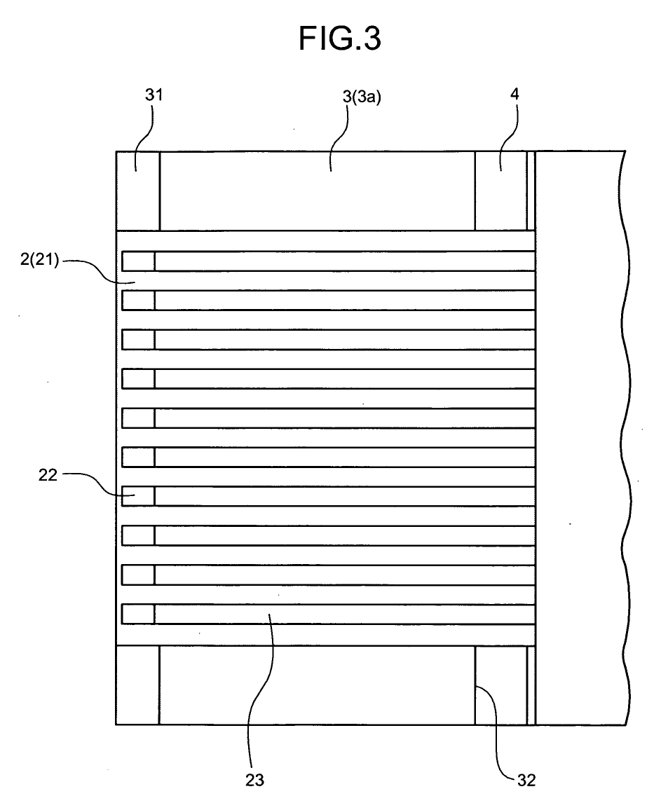

FIG. 1 is a schematic of a probe unit according to a first embodiment of the present invention. FIG. 2 is an external view of relevant portions of the probe unit, seen from a direction A shown in FIG. 1, and FIG. 3 is a bottom view of a portion near the distal end of the probe unit, seen from a direction B shown in FIG. 1. The probe unit 1 shown in FIGS. 1 to 3 is used to test the conductive state or operating characteristics of a test object before completion. Further, the probe unit 1 includes: a probe sheet 2 that has a plurality of probes that come in contact with a circuitry, provided in a test object or a circuit to be tested, so as to input and output electrical signals; a probe holder 3 that holds the probe sheet 2; a fixing member 4 that fixes the probe sheet 2 to the probe holder 3; and an adjustment mechanism 5 that adjusts contact positions where the probe holder and the test object contact each other.

The probe sheet 2 includes a sheet-like base 21 made of an insulating material such as polyimide, a plurality of bumps 22 that are arranged in a predetermined pattern near outside ends of the probe unit 1 along a width direction of the base 21, and that serve as contact sections coming into direct contact with a test object 200 such as a liquid crystal display or an integrated circuit, and a plurality of wires 23 each having one end on each of the bumps 22 as a base point and formed in parallel at predetermined intervals on a surface (lower side surface in FIG. 1) of the probe sheet 2 along a longitudinal direction thereof. The bumps 22 and the wires 23 are formed of nickel or the like, and a pair of a bump 22 and a wire 23 constitute one probe element.

The arrangement positions of the bumps 22 are defined corresponding to an arrangement pattern of the connecting electrodes or terminals provided on the test object 200, with which the bumps 22 come in contact. Although FIG. 3 depicts the bumps 22 linearly arranged for convenience, the bumps 22 may be arranged in a staggered or stitching pattern. The number of bumps 22 and the wires 23 shown in FIG. 3 is also an example, and hundreds of the bumps 22 and the wires 23 may be arranged in one probe unit 1 corresponding to the wiring pattern on the test object 200. The bumps 22 may have a different shape other than the rectangular solid shown in FIG. 1 or the like, such as a substantially cone or frustum shape.

The probe holder 3 includes a distal end 3a that holds the probe sheet 2, a proximal end 3b that is fixed to the adjustment mechanism 5 to support the distal end 3a, and a flexure-causing section 3c (flexure-causing unit) that resides between the distal end 3a and the proximal end 3b and causes a flexure of the distal end 3a relative to the proximal end 3b. The probe holder 3 is made of: metal such as stainless, aluminum, phosphor bronze, iron-base alloy, nickel alloy, copper-base alloy, tungsten, silicon, or carbon; ceramic such as aluminum (Al₂O₃), zirconia (ZrO₂), or Silica (SiO₂); thermosetting resin such as epoxy; super engineering plastic such as polyimide; or the like.

The bottom surface of the distal end 3a has a protruding portion 31 that is fixed on an upper surface of an outside end of the probe sheet 2, i.e. an outside end on which the bumps 22 are arranged, and an opening 32 that penetrates in a through-thickness direction of the distal end 3a (vertical direction in FIG. 1). Through the opening 32 is inserted the probe sheet 2 that is bonded to the protruding portion 31. The probe sheet 2 is fixed with the fixing member 4 provided on an upper surface of the distal end 3a, so as not to fall off from the distal end 3a. The protruding portion 31 may be constituted by an elastic member such as silicon rubber.

The flexure-causing section 3c is positioned between the distal end 3a and the proximal end 3b of the probe holder 3, and integrally formed with the distal end 3a and the proximal end 3b using the same material. The flexure-causing section 3c includes a groove 33 provided from the upper surface of the probe holder 3 to have a longitudinal cross section of a claw shape, so that a small-thickness portion 34 having a beam shape is formed to serve as a plate spring. As such, in the first embodiment, because the small-thickness portion 34 is formed by providing the groove 33 having the longitudinal cross section of a claw shape, the small-thickness portion 34 can be made longer compared with a small-thickness portion formed by simply cutting out, in a through-thickness direction, a base having the same length as that of the probe holder 3 in the horizontal direction in FIG. 1. This is efficient in using space and suitable for downsizing the probe holder 3.

The specific shape (thickness, length, etc.) of the flexure-causing section 3c having the above structure is determined based on the Hooke's law depending on the stroke, the contact load, or other factors required for each probe element. Thus, desirable spring characteristics can be given depending on the shape. For example, the shape of the flexure-causing section 3c is arranged such that the bumps 22, serving as probe elements, make a stroke of about 300 micrometers for a contact load of about 5 grams. With this arrangement, the spring characteristics are achieved that are equivalent to those achieved by applying pin probes.

The adjustment mechanism 5 includes a first block member 51 that is attached to and held by a certain frame substrate (not shown), and a second block member 52 that is fixed on the probe holder 3. Further, the adjustment mechanism 5 serves to adjust the vertical positional relationship between the first block member 51 and the second block member 52, so as to adjust the height of the probe holder 3 (the position in the vertical up-and-down direction in FIG. 1). The second block member 52 is fixed on the upper surface of the probe holder 3 with screws or the like.

To bring the test object 200 and the bumps 22 into contact with each other using the probe unit 1 having the above structure, the position of the probe holder 3 is adjusted by the adjustment mechanism 5, and the test object 200 is moved vertically upward in FIG. 1. In this way, the connecting electrodes or terminals on the test object 200 (not shown) are brought into physical contact with the bumps 22. It is desirable that the test object 200 be moved at a controlled speed such that a contact load not producing an excessive contact resistance is applied.

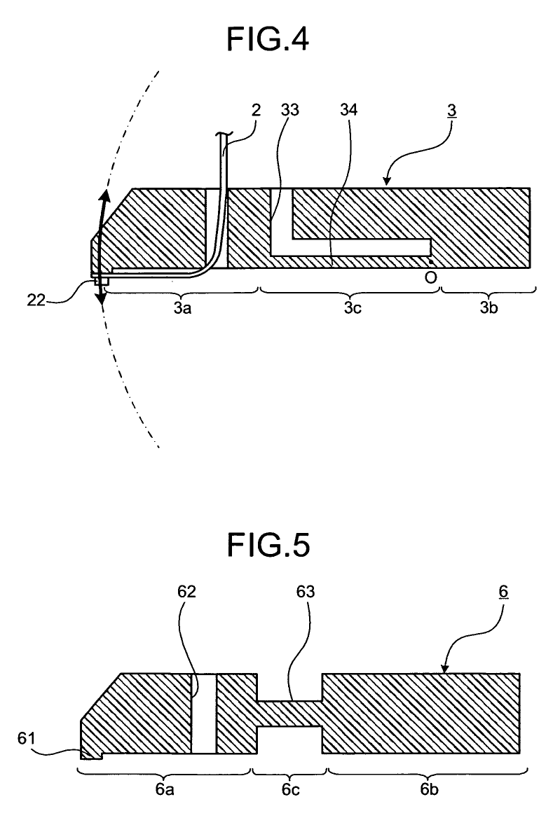

When the test object 200 comes in contact with the bumps 22, the load applied by the test object 200 causes a flexure of the distal end 3a relative to the proximal end 3b, causing a stroke that draws a path of a substantially arc about a point O, as a rotation center, near an interface between the flexure-causing section 3c and the proximal end 3b (both directions of arrows indicated in FIG. 4). Accordingly, when the bumps 22 come in contact with the surface of the test object 200, the bumps 22 slightly move in a direction parallel to the surface of the test object 200, as well as in a direction perpendicular to the surface. With such slight movement, the bumps 22 scratch the surface of the test object 200 and remove an oxide film formed on the surface or contamination adhered to the surface, thereby achieving more stable electric contact between the bumps 22 and the test object 200.

After the bumps 22 are brought into contact with the test object 200, a signal processor 100 outputs to the test object 200 a testing electrical signal. Specifically, an electrical signal generated and output by the signal processor 100 is input to the test object 200, via the wires 23 and the bumps 22 of the probe sheet 2 and the electrodes or terminals on the test object 200. The electrical signal is processed in an electric circuit (not shown) provided in the test object 200, and a response signal is output from the test object 200 to the signal processor 100. The signal processor 100 performs processing using the response signal received from the test object 200 via the bumps 22 and the wires 23, so as to determine whether the test object 200 has desirable characteristics.

According to the first embodiment of the present invention, a probe holder and a probe unit are provided that include: a distal end that has a plurality of probes that come in contact with a circuitry, so as to input and output an electrical signal to and from the circuitry; a proximal end that supports the distal end; and a flexure-causing section that resides between the distal end and the proximal end and causes a flexure of the distal end relative to the proximal end. In the probe holder and the probe unit, at least a portion of the flexure-causing unit is integrally formed with the distal end and the proximal end, and constitutes a beam plate having a thickness smaller than those of the distal end and the proximal end. With this structure, the probe holder and the probe unit ensure a desirable stroke upon contacting the test object, i.e. the circuitry, thereby achieving excellent durability and economic advantages.

According to the first embodiment, the probe holder, formed in an integrated unit using the same material, has a mechanism for internally causing a flexure, thereby enabling simple and compact structure and reducing the number of components, compared with a related-art probe holder having a complex external spring mechanism. This is economically advantageous because the production cost is lowered and maintenance is easy, while facilitating downsizing.

According to the first embodiment, when a load is applied to the bumps serving as probe contact sections, each of the bumps make a stroke as if drawing an arc due to the flexure of the flexure-causing section. This enables to scratch the surface of the test object, with which the bumps come in contact, so as to remove an oxide film formed on the surface and the contamination adhered to the surface. Thus, stable electric contact is achieved.

In addition, according to the first embodiment, the groove of the flexure-causing section is formed so as to penetrate the main body of the probe holder along the arrangement direction of the probe elements. This provides such an advantage as correcting deformation that occurs on the distal end relative to the proximal end due to the warp of the test object, when the probe holder comes in contact with the test object.

### Modification of First Embodiment

FIG. 5 is a schematic of a probe holder according to a modification of the first embodiment. FIG. 5 depicts a cross section taken in the same plane as the cross section shown in FIG. 1. A probe holder 6 shown in FIG. 5 includes a distal end 6a (including a protruding portion 61 and an opening 62), a proximal end 6b, and a flexure-causing section 6c. The flexure-causing section 6c, made of the same material as those of the distal end 6a and the proximal end 6b, includes a small-thickness portion 63 having a beam shape and formed-with its top and bottom portions cut out in the through-thickness direction. The small-thickness portion 63 has spring characteristics similarly to the small-thickness portion 34 of the flexure-causing section 3c. Thus, the probe holder 6 achieves the same advantageous effects as the probe holder 3 according to the first embodiment. Needless to say, the shape (length, thickness, etc.) of the flexure-causing section 6c is determined according to the stroke, the contact load, or other factors required for a probe unit that includes the probe holder 6 as a constituting element.

In addition to the above structure, the flexure-causing section may include, for example, a small-thickness portion formed such that only its bottom portion is cut out and its top surface forms the same surface as the top surfaces of the distal end 6a and the proximal end 6b. Alternatively, a small-thickness portion may be formed such that only its top portion is cut out and its bottom surface forms the same surface as the bottom surfaces of the distal end 6a and the proximal end 6b.

The proximal end and the distal end may have different through-thicknesses. The proximal end may have a through-thickness thicker than that of the distal end so as to securely support the distal end with the flexure-causing section therebetween.

### Second Embodiment

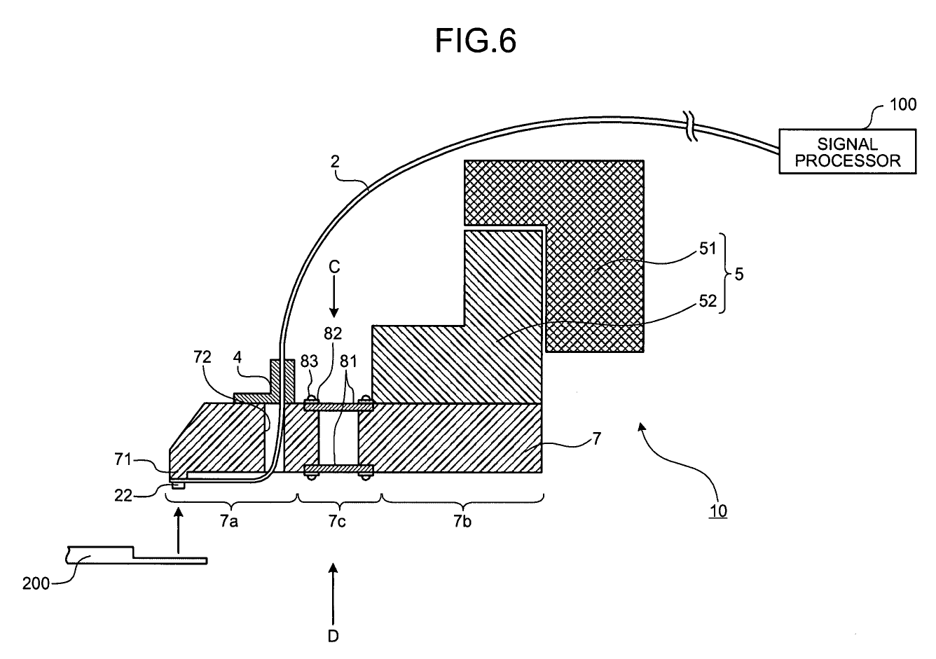

FIG. 6 is a schematic of a probe unit according to a second embodiment of the present invention. As in the probe holder 3 according to the first embodiment, a probe unit 10 shown in FIG. 6 is used to test the conductive state and operating characteristics of a test object before completion, and includes the probe sheet 2 (including the base 22, the bumps 22, and the wires 23), a probe holder 7, the fixing member 4, and the adjustment mechanism 5 (including the first block member 51 and the second block member). Because the components other than the probe holder 7 are the same as those of the probe unit 1, the same reference numerals are given to the corresponding components and the description thereof is omitted.

The following describes the probe holder 7. The probe holder 7 includes a distal end 7a that holds the probe-sheet 2, a proximal end 7b that is fixed to the adjustment mechanism 5 to support the distal end 7a, and a flexure-causing section 7c (flexure-causing unit) that resides between the distal end 7a and the proximal end 7b and causes a flexure of the distal end 7a relative to the proximal end 7b. The distal end 7a has a protruding portion 71 that bonds and fixes an upper surface of an outside end of the probe sheet 2, i.e. an outside end on which the bumps 22 are arranged, and an opening 72 that penetrates the distal end 3a in a through-thickness direction thereof (vertical direction in FIG. 6). Through the opening 72 is inserted the probe sheet 2. The probe sheet 2 is fixed with the fixing member 4 provided on an upper surface of the distal end 7a, so as not to fall off from the distal end 7a. The proximal end 7b is fixed to the second block member 52 of the adjustment mechanism 5 with screws or the like.

The distal end 7a and the proximal end 7b have the same through-thickness, and are made of the same material (such as metal, ceramic, thermosetting resin, or super engineering plastic) as that of the probe holder 3 according to the first embodiment. The distal end 7a and the proximal end 7b may be formed of different materials.

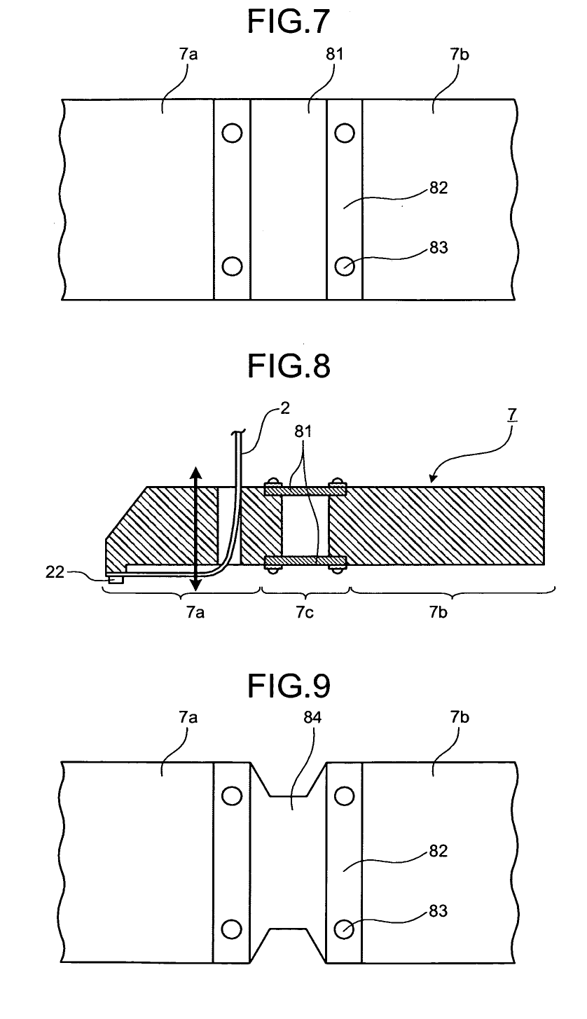

The flexure-causing section 7c is constituted separately from the distal end 7a and the proximal end 7b. Specifically, the flexure-causing section 7c includes two plate springs 81 having the same shape and arranged in parallel, fixing plates 82 that fix the plate springs 81 to the distal end 7a and the proximal end 7b, and screws 83 that fasten the plate springs 81 and the fixing plates 82 to the distal end 7a and the proximal end 7b. FIG. 7 is a partial view showing a portion of the flexure-causing section 7c, seen from a direction of an arrow C indicated in FIG. 6. In FIG. 7, a plate spring 81 has a rectangular thin plate shape, and its ends facing each other and constituting the long sides of the plate spring 81 are respectively fastened to the distal ends 7a and 7b, with the screws 83 with the fixing plates 82 therebetween. In this way, the top surfaces of the distal end 7a and the proximal end 7b are connected to each other in a direction (horizontal direction in FIG. 6) orthogonal to the through-thickness direction. A partially perspective view seen from a direction of an arrow D indicated in FIG. 6 is the same as shown in FIG. 7, and the bottom surfaces of the distal end 7a and the proximal end 7b are connected to each other.

The plate springs 81 are made of phosphor bronze, and its shape (thickness, surface area, etc.) is determined based on the Hooke's law depending on the stroke, the contact load, or other factors required for the probe unit 10. The plate springs 81 can be made of: metal such as nickel, nickel beryllium, or stainless, as well as phosphor bronze; ceramic such as aluminum (Al₂O₃), zirconia (ZrO₂), or silica (SiO₂); thermosetting resin such as epoxy; or the like.

According to the second embodiment, the shape of the flexure-causing section 7c (the thickness and the surface area of the plate springs, etc.) is determined more specifically based on the Hooke's law depending on the stroke, the contact load, or other factors required for each probe element. Thus, desirable spring characteristics (for example, as in the first embodiment, the spring characteristics equivalent to those of the pin probe) can be given depending on the shape. In this manner, arranging the two plate springs 81 in parallel improves the accuracy of contact positions between the bumps 22 and the test object 200. However, in general, the two plate springs 81 may not necessarily be provided in parallel.

When the test object 200 and the bumps 22 are brought into contact with each other using the probe unit 10 having the above structure, the position of the probe holder 7 is adjusted by the adjustment mechanism 5, and the test object 200 is moved vertically upward in FIG. 6. In this way, the connecting electrodes or terminals on the test object 200 are brought into physical contact with the bumps 22. When brought into contact with the bumps 22, it is more preferable that the test object 200 be moved at a controlled speed such that a contact load not producing an excessive contact resistance is applied.

When the test object 200 contacts the bumps 22, a load applied by the test object 200 causes a flexure on the flexure-causing section 7c. As a result, a stroke is made on each of the bumps 22 such that the distal end 7a moves up and down along the through-thickness direction relative to the proximal end 7b, as shown in FIG. 8 (both directions of arrows indicated in FIG. 8). The direction in which such a stroke occurs is substantially parallel to a direction in which the test object 200 approaches the bumps 22. Thus, the probe holder 7 according to the second embodiment is preferably used for the test object 200 having a high-definition structure and requiring high accuracy for contact positioning.

The plate springs applied to the flexure-causing section 7c may have a surface shape other than a rectangular. FIG. 9 depicts another surface shape of a plate spring applied as a flexure-causing section. The plate spring 84 shown in FIG. 9 has cutout portions forming a taper shape at substantially center part of the short sides of the rectangular. The plate spring 84 having such a shape provides an advantage as making a stress applied thereon uniform and a stroke of the distal end 7a in the probe holder 7 larger.

According to the second embodiment of the present invention, a probe holder and a probe unit are provided that include: a distal end that has a plurality of probes that come in contact with a circuitry, so as to input and output an electrical signal to and from the circuitry; a proximal end that supports the distal end; and a flexure-causing section that resides between the distal end and the proximal end and causes a flexure of the distal end relative to the proximal end. In the probe holder and the probe unit, the flexure-causing unit includes elastic members (plate springs) that connect the distal end and the proximal end. With this structure, the probe holder and the probe unit ensure a desirable stroke upon contacting the test object, i.e. the circuitry, thereby achieving excellent durability and economic advantages.

According to the second embodiment, as in the related-art external spring mechanism, a stroke mainly occurs in a direction substantially parallel to the through-thickness direction of the probe holder. This structure is preferable when high accuracy testing is required. Particularly in the second embodiment, because a complex spring mechanism is not necessary, a simple and compact structure is achieved, facilitating downsizing. Thus, high accuracy testing is realized at low cost according to the second embodiment.

### Modification of Second Embodiment

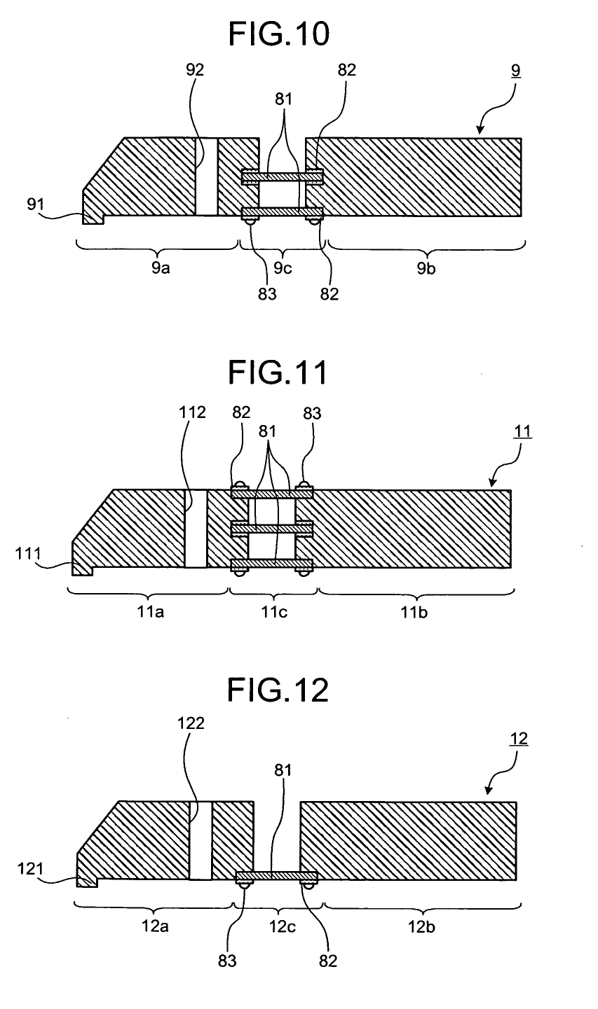

FIG. 10 is a schematic of a probe holder according to a first modification of the second embodiment. FIG. 10 depicts a cross section taken in the same plane as the cross section shown in FIG. 6. A probe holder 9 shown in FIG. 10 includes a distal end 9a (including a protruding portion 91 and an opening 92), a proximal end 9b, and a flexure-causing section 9c. The flexure-causing section 9c is constituted by the two plate springs 81. One of the plate springs 81 connects substantially center portions, in the through-thickness direction, of the distal end 9a and the proximal end 9b, and the other connects bottom surfaces of the distal end 9a and the proximal end 9b.

When the distal end of the probe elements (for example, the bumps 22 shown in FIG. 6) held in the probe holder 9 having the above structure, come into physical contact with the test object and a load is applied to the probe elements, a stroke occurs as in the probe holder 7 such that the distal end 9a fluctuates along the through-thickness direction relative to the proximal end 9b. Thus, the probe holder 9 achieves the same advantages as the probe holder 7.

In the second embodiment, although the foregoing describes the structure in which the two plate springs 81 (or the two plate springs 84) are used to constitute the flexure-causing section, the number of the plate springs used is not limited to two. FIG. 11 depicts a cross section of the same shape that employs three plate springs according to a second modification of the second embodiment. In a probe holder 11 shown in FIG. 11, a flexure-causing section 11c includes three plate springs 81 that connect a distal end 11a (including a protruding portion 111 and an opening 112) and a proximal end 11b so as to cause a flexure of the distal end 11a relative to the proximal end 11b. As is apparent from this modification, the number of plate springs used in the flexure-causing section may be determined depending on the stroke, the contact load, or other factors required for the probe unit.

When a plurality of plate springs are used as the flexure-causing section, each of the plate springs may have a different thickness or shape.

### Third Embodiment

FIG. 12 is a cross sectional view of a probe holder according to a third embodiment of the present invention. A probe holder 12 shown in FIG. 12 includes a distal end 12a (including a protruding portion 121 and an opening 122), a proximal end 12b, and a flexure-causing section 12c. The flexure-causing section 12c includes the plate spring 81 that connects bottom surfaces of the distal end 12a and the proximal end 12b, the fixing plates 82 that fix the plate springs 81, and the screws 83 that fasten the plate spring 81 to the distal end 12a and the proximal end 12b at predetermined positions with the fixing plates 82 therebetween.

When the probe holder 12 having the above structure is used to perform testing, a stroke occurs as if drawing an arc upon contacting the test object, as in the first embodiment. This enables to scratch the surface of the test object, so as to remove an oxide film formed on the surface and the contamination adhered to the surface. Needless to say, the third embodiment of the present invention achieves the same advantages as the first embodiment.

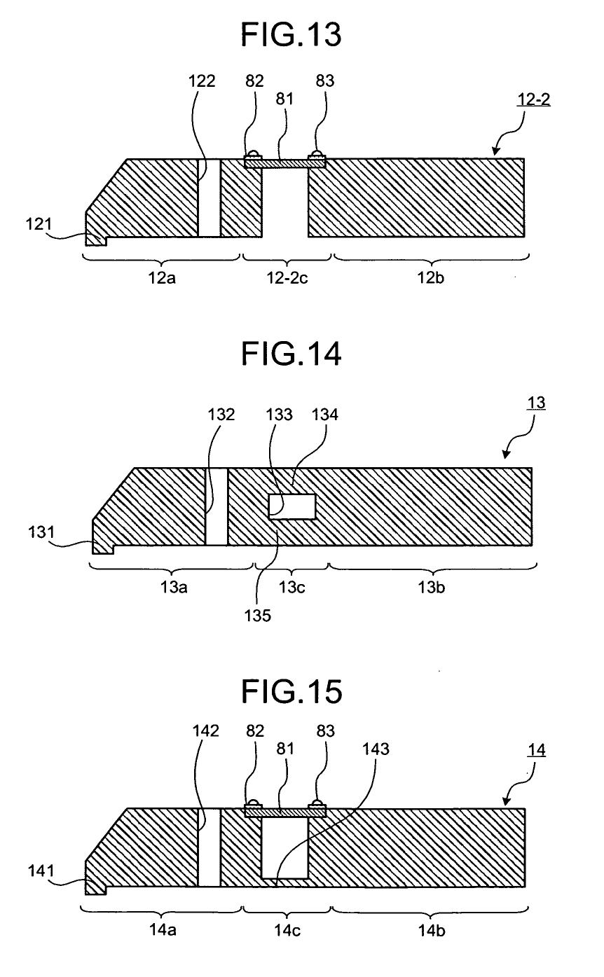

A probe holder shown in FIG. 13 can be configured as a modification of the third embodiment. A probe holder 12-2 shown in FIG. 13 includes the distal end 12a and the proximal end 12b as in the probe holder 12. Between the distal end 12a and the proximal end 12b resides a flexure-causing section 12-2c that causes a flexure of the distal end 12a relative to the proximal end 12b. The flexure-causing section 12-2c constituted by a single plate spring 81 differs from the probe holder 12 in that the top surfaces of the distal end 12a and the proximal end 12b are connected to each other with the fixing plates 82 and the screws 83. Needless to say, when the probe holder 12-2 having the above structure is used to perform testing, a stroke also occurs as if drawing an arc when the probe holder 12-2 comes in contact with the test object.

In the third embodiment, a probe unit has the same structure as those of the first and the second embodiments, except the probe holder. Further, the material used for the probe holder and the plate springs are also the same as those in the first and the second embodiments. In this regard, the same applies to a fourth and a fifth embodiments described later.

### Fourth Embodiment

FIG. 14 is a cross sectional view of a probe holder according to a fourth embodiment of the present invention. A probe holder 13 shown in FIG. 14 includes a distal end 13a (including a protruding portion 131 and an opening 132), a proximal end 13b, and a flexure-causing section 13c. The flexure-causing section 13c includes an opening 133 that is formed by wire cutting process or the like so as to penetrate in a direction perpendicular to the through-thickness direction. Two small-thickness portions 134 and 135, respectively provided above and below the opening 133 in the through-thickness direction, serve as the two plate springs 81 that constitute the flexure-causing section 6c of the probe holder 6 according to the second embodiment. To this end, the two small-thickness portions 134 and 135 have substantially the same thickness.

According to the fourth embodiment of the present invention having the above structure, the two small-thickness portions 134 and 135 serve as the two plate springs 81 according to the second embodiment. Thus, when the bumps 22 on the probe sheet 2 held in the probe holder 6 contact the test object, a stroke occurs such that the distal end 13a fluctuates along the through-thickness direction relative to the proximal end 13b, thereby achieving the same advantages as the second embodiment. In addition, the probe holder according to the fourth embodiment can be formed integrally with the same material. This realizes a reduction in the number of components and facilitates production, achieving a further cost reduction.

The small-thickness portions provided above and below the opening formed in the flexure-causing section may have different thicknesses. Although the foregoing describes the flexure-causing section having one opening formed therein, two or more openings may be formed that penetrate in parallel to each other in a direction perpendicular to the through-thickness direction.

### Fifth Embodiment

FIG. 15 is a cross sectional view of a probe holder according to a fifth embodiment of the present invention. A probe holder 14 shown in FIG. 15 includes a distal end 14a (including a protruding portion 141 and an opening 142), a proximal end 14b, and a flexure-causing section 14c. The flexure-causing section 14c is formed integrally with the distal end 14a and the proximal end 14b using the same material. The flexure-causing section 14c includes a small-thickness portion 143 that integrally connects bottom surfaces of the distal end 14a and the proximal end 14b, the plate spring 81 that connects top surfaces of the distal end 14a and the proximal end 14b, the fixing plates 82 that fix the plate spring 81, and the screws 83 that fasten the plate spring 81 to predetermined positions of the distal end 14a and the proximal end 14b with the fixing plates 82 therebetween.

According to the fifth embodiment of the present invention having the above structure, a stroke occurs along the through-thickness direction due to the flexure of the plate spring 81 and the small-thickness portion 143, thereby achieving the same advantages as the second embodiment.

### Other Embodiments

The foregoing specifically describes exemplary embodiments for carrying out the present invention. The present invention should not be limited to the first to the fifth embodiments, and those embodiments may be suitably combined to constitute different embodiments.

Further, the foregoing is described assuming that a probe unit is used for testing a liquid crystal display. The present invention is also applicable to a high-density probe unit used for testing a package substrate or a wafer level on which a semiconductor chip is mounted.

The foregoing describes arrangements in which a probe sheet is applied. The present invention is also applicable to an arrangement in which a pin probe or blade probe using a coil spring is employed.

As such, the present invention may include various embodiments that are not described herein, and various design changes or the like may be made within the scope of technical ideas specified by the patent claims.

### INDUSTRIAL APPLICABILITY

As described, a probe holder and a probe unit according to the present invention are useful for holding a plurality of probes that come in contact with a circuitry such as an LCD or an integrated circuit, so as to input and output electrical signals, when testing the conductive state or operating characteristics of the circuitry.

1: A probe holder for containing a plurality of probes for inputting and outputting an electrical signal to and from a circuitry when the probes come in contact with the circuitry, the probe holder comprising:
a distal end for holding the probes;
a proximal end that supports the distal end; and
a flexure-causing unit between the distal end and the proximal end to cause a flexure of the distal end relative to the proximal end.

2: The probe holder according to claim 1, wherein the flexure-causing unit has at least a portion formed integrally with the distal end and the proximal end and having a beam shape with a thickness smaller than thicknesses of the distal end and the proximal end.

3: The probe holder according to claim 1, wherein the flexure-causing unit includes an elastic member that connects the distal end and the proximal end.

4: The probe holder according to claim 3, wherein the elastic member includes at least one spring plate.

5: A probe unit comprising:
a plurality of probes for inputting and outputting an electrical signal to and from a circuitry when the probes come in contact with the circuitry; and
a probe holder including a distal end for holding the probes, a proximal end that supports the distal end, and a flexure-causing unit between the distal end and the proximal end to cause a flexure of the distal end relative to the proximal end.

6: The probe unit according to claim 5, wherein the flexure-causing unit has at least a portion formed integrally with the distal end and the proximal end and having a beam shape with a thickness smaller than thicknesses of the distal end and the proximal end.

7: The probe unit according to claim 5, wherein the flexure-causing unit includes an elastic member that connects the distal end and the proximal end.

8: The probe unit according to claim 7, wherein the elastic member includes at least one spring plate.

9: The probe unit according to claim 5, wherein the probes include wiring formed on a surface of a sheet-like base, and a contact section arranged on one end of the wiring and coming into direct contact with the circuitry.
